(19) United States
(12) Patent Application Publication
(10) Pub. No.: US 2026/0162702 A1
(43) Pub. Date: Jun. 11, 2026

(54) TECHNIQUES FOR READ BURST ORDERING CONTROL AT A MEMORY SYSTEM

(71) Applicant: Micron Technology, Inc., Boise, ID (US)

(72) Inventor: Jongtae Kwak, Carrollton, TX (US)

(21) Appl. No.: 19/380,449

(22) Filed: Nov. 5, 2025

Related U.S. Application Data
(60) Provisional application No. 63/730,371, filed on Dec. 10, 2024.

(51) Int. Cl. G11C 7/22; G11C 7/10; G11C 29/52

(52) U.S. Cl. CPC G11C 7/222; G11C 7/1036; G11C 7/1066; G11C 7/1069; G11C 29/52

(57) ABSTRACT

Methods, systems, and devices for techniques for read burst ordering control at a memory system are described. The described techniques provide for a memory system to output offset data read signals according to activation of either a count start even signal or a count start odd signal. A first control circuit may receive the count start odd signal at a data input and the count start even signal at a set/reset input, and a second control circuit may receive the count start even signal at a data input and the count start odd signal at a set/reset input. Based on the values of the count start even signal and the count start odd signal, one of the shift register outputs may be delayed relative to the other shift register output.

### CROSS REFERENCE

The present Application for Patent claims priority to U.S. patent application Ser. No. 63/730,371 by Kwak, entitled “TECHNIQUES FOR READ BURST ORDERING CONTROL AT A MEMORY SYSTEM,” filed Dec. 10, 2024, which is assigned to the assignee hereof, and which is expressly incorporated by reference in its entirety herein.

### TECHNICAL FIELD

The following relates to one or more systems for memory, including techniques for read burst ordering control at a memory system.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports techniques for read burst ordering control at a memory system in accordance with examples as disclosed herein.

FIG. 2 shows an example of an architecture that supports techniques for read burst ordering control at a memory system in accordance with examples as disclosed herein.

FIG. 3 shows an example of a timing diagram that supports techniques for read burst ordering control at a memory system in accordance with examples as disclosed herein.

FIG. 4 shows an example of an architecture that supports techniques for read burst ordering control at a memory system in accordance with examples as disclosed herein.

FIG. 5 shows an example of a timing diagram that supports techniques for read burst ordering control at a memory system in accordance with examples as disclosed herein.

FIG. 6 shows a block diagram of a memory system that supports techniques for read burst ordering control at a memory system in accordance with examples as disclosed herein.

FIG. 7 shows a flowchart illustrating a method or methods that support techniques for read burst ordering control at a memory system in accordance with examples as disclosed herein.

### DETAILED DESCRIPTION

Memory systems may be provided to output data in response to receiving a command to read the data from one or more memory cells of the memory system. In some cases, the memory system may output the data according to a data read burst. Data read bursts may be controlled by a divided clock (e.g., divided from an external clock received from a host system), such that the memory system may use two data read signals according to the divided clocks. For example, a first shift register may output a first data read signal according to a first division of the external clock (e.g., data read even) and a second shift register may output a second data read signal according to a second division of the external clock (e.g., data read odd). Each shift register may include a quantity of latches to output sequential values for retrieving data bits. Such techniques may enable the memory system to prepare data read bits for one data read output while transmitting the data read bits for the other data read output. In some cases, due to the division of the clock, a read command may be received before one of a rising or falling edge of either clock signal. Based on when the read command is received, the data read even signal or the data read odd signal may output first, and the other signal may output after a delay.

To control which signal is output first, a count start value may be activated (e.g., initiated to a first value) according to which edge (e.g., rising edge) the read command is received before. For example, a count start even signal may be activated if the read command is received before the rising edge of the data read clock even and a count start odd signal may be activated if the read command is received before the rising edge of the data read clock odd. In some cases, the same techniques may be used with the falling edges of the clocks. To output the data read signals according to an appropriate pattern, the memory system may include two sets of circuitry for outputting the data read signals, where a first set of circuitry may activate in response to the count start even signal and a second set of circuitry may activate in response to the count start odd signal. However, implementing the two sets of circuitry may occupy relatively large space in the memory system and may incur additional power consumption (e.g., due to maintaining 20 flip-flops despite only 10 being active for a given read command).

Techniques described herein provide for a memory system that includes one set of circuitry for outputting offset data read signals according to activation of either a count start even or a count start odd signal. For example, a first shift register may output a data read even signal and a second shift register may output a data read odd signal. Each shift register may be controlled by a respective control circuit (e.g., a set/reset latch), which may receive each of the count start even and the count start odd signal. For example, the first shift register may receive the count start odd signal at a data input of a first control circuit and the count start even signal at a set/reset input of the first control circuit, and the second shift register may receive the count start even signal at a data input of a second control circuit and the count start odd signal at a set/reset input of the second control circuit. Based on the values of the count start even signal and the count start odd signal, one of the shift register outputs may be delayed relative to the other shift register output. For example, the first control circuit may be set by the count start even signal (e.g., activating the first shift register and outputting the data read even signal) and the second control circuit may be set by the count start odd signal (e.g., activating the second shift register and outputting the data read odd signal). Such techniques may reduce space occupied by the circuitry and reduce power expenditure by the memory system when outputting data read signals.

In addition to applicability in memory systems as described herein, techniques for read burst ordering control may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing power expenditure and space occupied by burst ordering control circuity, which may decrease processing or latency times, improve response times, or otherwise improve user experience, among other benefits.

In addition to applicability in memory systems as described herein, techniques for read burst ordering control may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used electronic devices, which may reduce electronic waste and extend the life of electronic devices, thereby reducing electronic waste, among other benefits.

Features of the disclosure are illustrated and described in the context of systems and architectures. Features of the disclosure are further illustrated and described in the context of waveform diagrams, a block diagram, and a flowchart.

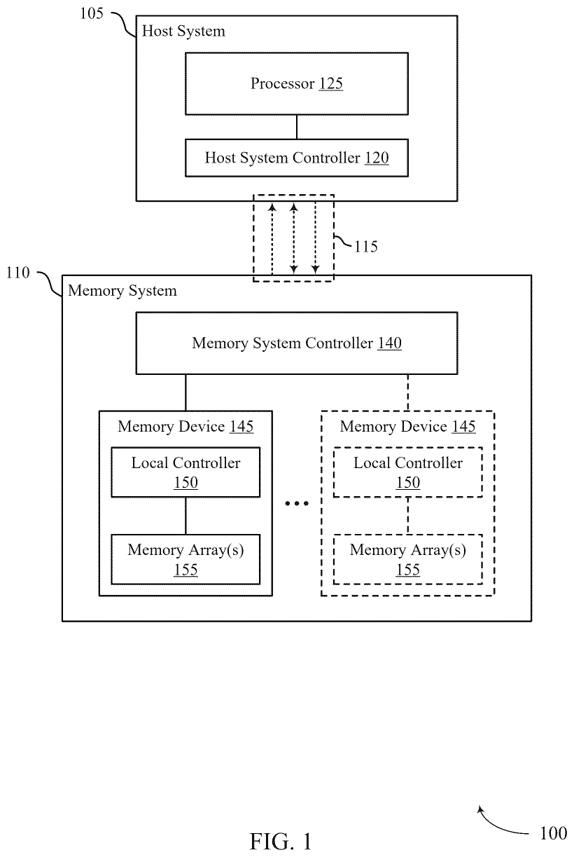

FIG. 1 shows an example of a system 100 that supports techniques for read burst ordering control at a memory system in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

In some examples of the system 100, a memory system 110 may output the data according to a data read burst. Data read bursts may be controlled by a divided clock (e.g., divided from an external clock received from a host system 105), such that the memory system 110 may output two data read signals according to the divided clocks. For example, a first shift register may output a first data read signal according to a first division of the external clock (e.g., data read even) and a second shift register may output a second data read signal according to a second division of the external clock (e.g., data read odd). Each shift register may include a quantity of flip-flop latches (e.g., 5 latches) to output sequential values for retrieving data bits. Such techniques may enable the memory system 110 to prepare data read bits for one data read output while transmitting the data read bits for the other data read output. In some cases, due to the division of the clock, a read command may be received before the rising edge of either clock signal. Based on when the read command is received, the data read even signal or the data read odd signal may output first, and the other signal may output after a delay.

To control which signal is output first, a count start value may be activated (e.g., initiated to a first value) according to which rising edge the read command is received before (of falling edge, if the clock systems are indexed to falling edges instead of rising edges). For example, a count start even signal may be activated if the read command is received before the rising edge of the data read clock even and a count start odd signal may be activated if the read command is received before the rising edge of the data read clock odd. To output the data read signals according to an appropriate pattern, the memory system 110 may include two sets of circuitry for outputting the data read signals, where a first set of circuitry may activate in response to the count start even signal and a second set of circuitry may activate in response to the count start odd signal. However, implementing the two sets of circuitry may occupy relatively large space in the memory system 110 and may incur additional power consumption (e.g., due to maintaining 20 flip-flops despite only 10 being active for a given read command).

In some cases, a memory system 110 may utilize one set of circuitry for outputting offset data read signals according to activation of either a count start even or a count start odd signal. For example, a first shift register may output a data read even signal and a second shift register may output a data read odd signal. Each shift register may be controlled by a respective control circuit (e.g., a set/reset latch), which may receive each of the count start even and the count start odd signal. For example, the first shift register may receive the count start odd signal at a data input of a first control circuit and the count start even signal at a set/reset input of the first control circuit, and the second shift register may receive the count start even signal at a data input of a second control circuit and the count start odd signal at a set/reset input of the second control circuit. Based on the values of the count start even signal and the count start odd signal, one of the shift register outputs may be delayed relative to the other shift register output. For example, the first control circuit may be set by the count start even signal (e.g., activating the first shift register and outputting the data read even signal) and the second control circuit may be set by the count start odd signal (e.g., activating the second shift register and outputting the data read odd signal). Such techniques may reduce space occupied by the clock circuitry and reduce power expenditure by the memory system 110 when outputting data read signals.

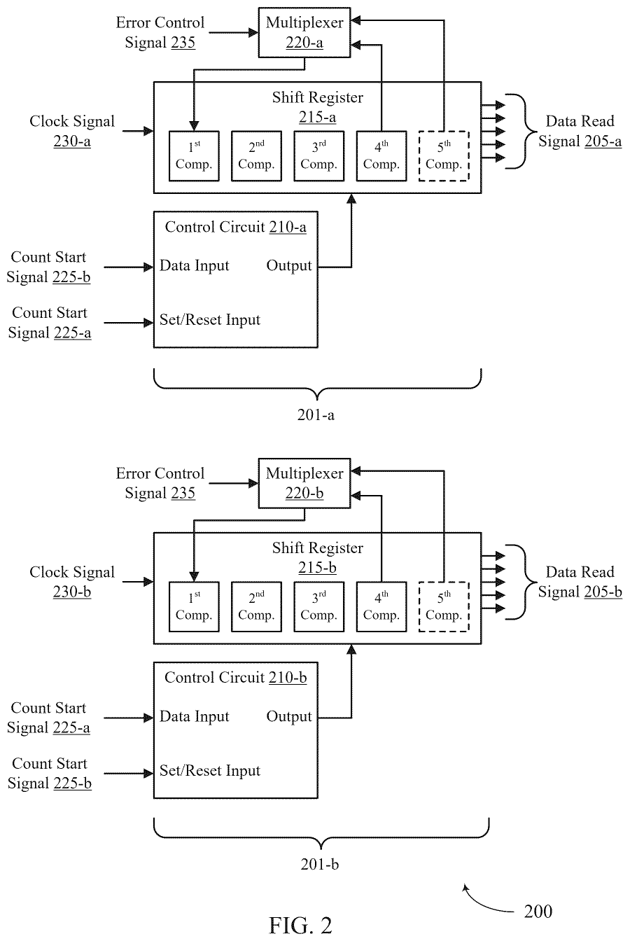

FIG. 2 illustrates an example of a clock circuit 200 that supports techniques for read burst ordering control at a memory system in accordance with examples as disclosed herein. The clock circuit 200 may implement, or be implemented by, one or more aspects of the system 100. For example, the clock circuit 200 shows an example of circuitry included in a memory system 110 described with reference to FIG. 1. In some examples, the clock circuit 200 may support the memory system outputting data read signals 205 for controlling data read bursts in response to a command to read data stored to one or more memory cells of the memory system.

In some examples, the clock circuit 200 may include two portions, such as a first portion 201-a of the clock circuit 200 and a second portion 201-b of the clock circuit 200. The first portion 201-a of the clock circuit 200 may output a first data read signal 205-a (which may be referred to as a data read even signal) and the second portion 201-b of the clock circuit 200 may output a second data read signal 205-b (which may be referred to as a data read odd signal), which may support the memory system retrieving data bits in response to receiving a read command. For example, a first output of the data read signal 205-a (e.g., value 0) may support retrieving a first set of bits (e.g., 2 bits) of the data, a first output of the data read signal 205-b (e.g., value 0) may support retrieving a second set of bits of the data, a second output of the data read signal 205-a (e.g., value 1) may support retrieving a third set of bits of the data, a second output of the data read signal 205-b (e.g., value 1) may support retrieving a fourth set of bits of the data, and so on, or vice versa (e.g., where the data read signal 205-b is output before the data read signal 205-a). Accordingly, a sequential output of one of the data read signals 205 may be offset from a corresponding sequential output of the other data read signal 205.

Each portion 201 of the clock circuit 200 may include similar sets of circuitry to support outputting respective data read signals 205. For example, the first portion 201-a may include a control circuit 210-a, a shift register 215-a, and a multiplexer 220-a, and the second portion 201-b may include a control circuit 210-b, a shift register 215-b, and a multiplexer 220-b.

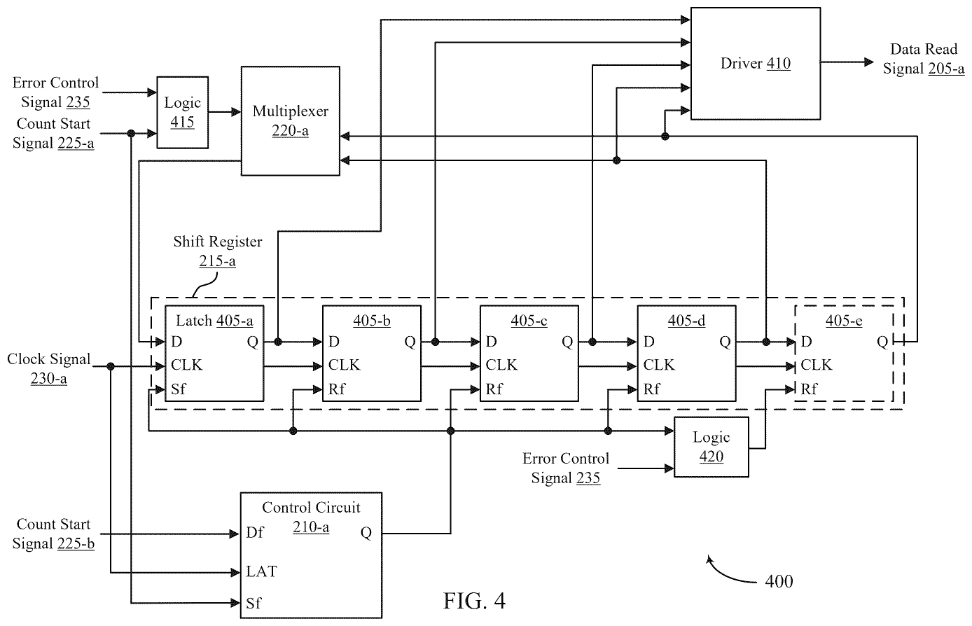

The control circuits 210 may be configured to activate a respective shift register 215 to begin outputting a respective data read signal 205. In some examples, the control circuits 210 may be examples of set/reset latches, and may include a respective data input, a respective set/reset input, and a respective output, as described in greater detail with reference to FIG. 4. As described herein, the control circuits 210 may be configured to receive each of a count start signal 225-a (which may be referred to as a count start even signal) and a count start signal 225-b (which may be referred to as a count start odd signal). For example, the control circuit 210-a may be configured to receive the count start signal 225-b at a data input of the control circuit 210-a and the count start signal 225-a at a set/reset input of the control circuit 210-a, and the control circuit 210-b may be configured to receive the count start signal 225-a at a data input of the control circuit 210-b and the count start signal 225-b at a set/reset input of the control circuit 210-b. Due to differences in the input of the count start signals 225 to the control circuits 210, respective values of the count start signals 225 may determine which data read signal 205 is output first.

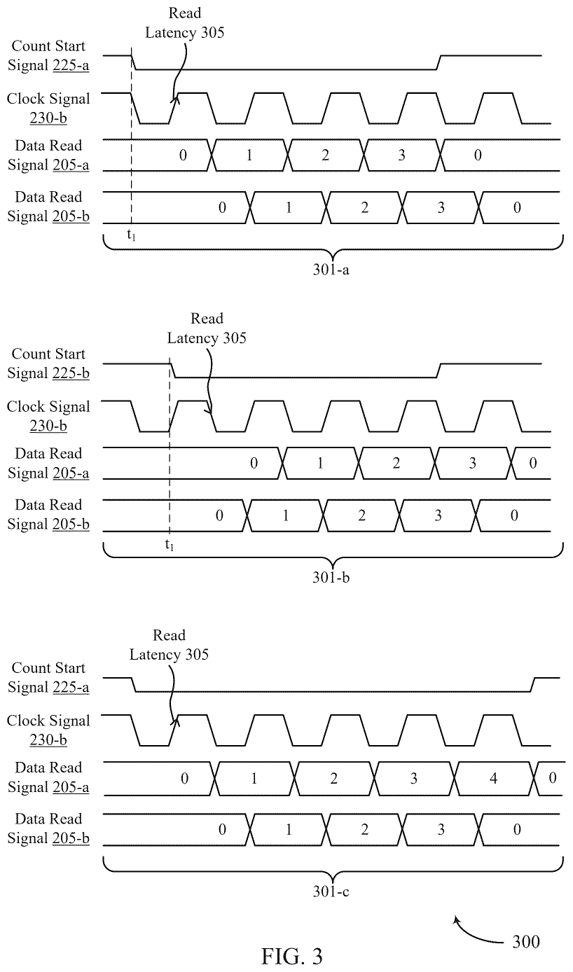

In response to receiving a read command, the memory system may initiate one of the count start signals 225 to a first value and may maintain the other of the count start signals 225 at a second value. The values of the count start signals 225 may be based on when the read command is received relative to a rising edge of one or more clock signals 230 (e.g., as described in greater detail with reference to FIG. 3). The one or more clock signals 230 may be examples of divided clock signals that are divided from an external clock (e.g., Ext CLK, which may be received from a host system). For example, the memory system may initiate a clock signal 230-a (e.g., DLLCLK180) and a clock signal 230-b (e.g., DLLCLK0) that operate at half of the frequency of the external clock, where the clock signal 230-b may be inverted relative to the clock signal 230-a. For example, a falling edge of clock signal 230-b corresponds to a rising edge of the clock signal 230-a, and vice versa. In some cases, the memory system may initiate the count start signal 225-a to the first value and may maintain the count start signal 225-b at the second value based on the read command being received before a rising edge of the clock signal 230-a. Alternatively, the memory system may initiate the count start signal 225-b to the first value and may maintain the count start signal 225-a to the second value based on the read command being received before a rising edge of the clock signal 230-b.

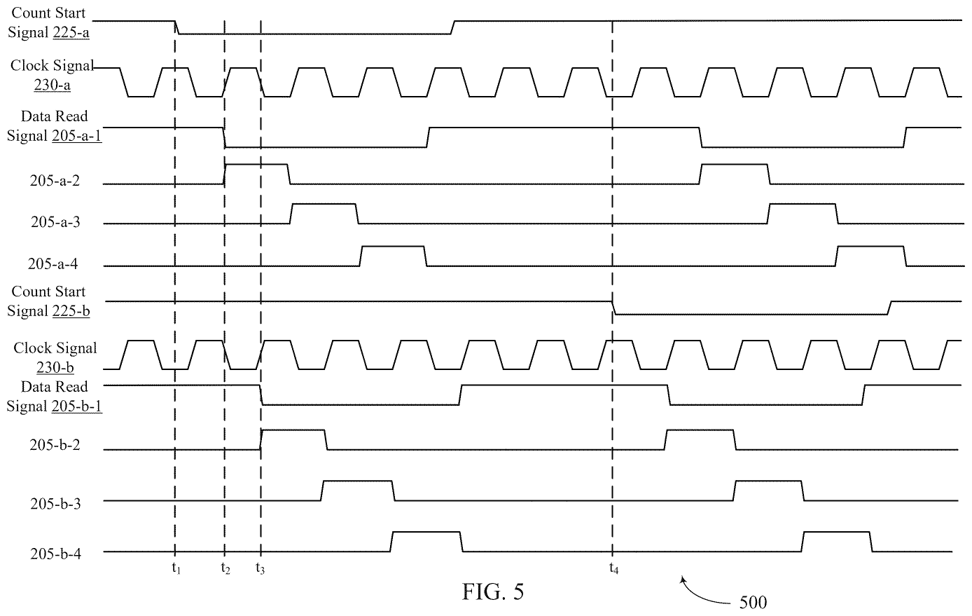

The shift registers 215 may be operated according to a respective clock signal 230 to output a respective data read signal 205. For example, the shift register 215-a may be operated according to the clock signal 230-a and the shift register 215-b may be operated according to the clock signal 230-b. The shift registers 215 may output the data read signal 205-a as a sequence of bits, for example bits stored to one or more components within the shift registers 215-a (e.g., flip-flops configured to latch and output bit values). Each component of a shift register 215 may receive the corresponding clock signal 230 and may output the respective value latched to the component to a subsequent component. For example, when the shift register 215-a receives the clock signal 230-a (e.g., a rising edge of the clock signal 230-a), the first component of the shift register 215-a may output a latched value (e.g., 1) as a least significant bit (LSB) of the data read signal 205-a and may output the latched value to the second component of the shift register 215-a. The components may sequentially shift the data such that the data read signal 205-a corresponds to an integer value according to which component of the shift register 215-a outputs a data ‘1’ (e.g., as described in greater detail with reference to FIGS. 4 and 5).

The multiplexers 220 may be operated to determine whether a corresponding data read signal 205 includes an additional bit for retrieving error control data. For example, the multiplexers 220 may receive an error control signal 235 indicating whether one of the data read signals 205 includes the additional bit. In some cases, the error control signal 235 may be compared with one of the count start signals 225 at each multiplexer 220 to prevent both data read signals 205 from including the additional bit, such as if the error control signal 235 is set to a value indicating the error control data is to be retrieved, as described in greater detail with reference to FIG. 4.

The configuration provided by the clock circuit 200 may improve performance of the memory system while controlling data read burst ordering, for example due to using less components and thereby reducing a footprint of the clock circuit 200 and reducing power expenditure.

FIG. 3 shows an example of a timing diagram 300 that supports techniques for read burst ordering control at a memory system in accordance with examples as disclosed herein. The timing diagram 300 may implement, or be implemented by, one or more aspects of the system 100 and the clock circuit 200. For example, the timing diagram 300 may be implemented by a memory system 110 described with reference to FIG. 1. Additionally, the timing diagram 300 may show a burst ordering control scheme and may include the count start signal 225-a, the count start signal 225-b, the clock signal 230-b, the data read signal 205-a, and the data read signal 205-b as described with reference to FIG. 2.

The timing diagram 300 illustrates a first scenario 301-a. In the scenario 301-a, a read command may be received at time t₁. For example, the read command may be received before a rising edge of the clock signal 230-a (e.g., before a falling edge of the clock signal 230-b, as illustrated in the scenario 301-a). For simplicity, the clock signal 230-a is not explicitly shown in FIG. 3. However, the clock signal 230-a is an inverted version of clock signal 230-b. Thus, a falling edge of clock signal 230-b corresponds to a rising edge of the clock signal 230-a, and vice versa. The memory system may initiate the count start signal 225-a to a first value based on the read command being received before the rising edge of the clock signal 230-a. Due to a read latency 305, the memory system may begin executing the read command according to the next rising edge of the clock signal 230-b. Based on the count start signal 225-a being initiated to the first value, the data read signal 205-a may output before the data read signal 205-b. For example, the data read signal 205-a may output a value 0 at a falling edge of the clock signal 230-b following the read latency 305 and the data read signal 205-b may output a value 0 at a rising edge of the clock signal 230-b (e.g., one unit interval of the clock signal 230-b following the output of the data read signal 205-a). The data read signals 205 may alternate outputting sequential data read values for retrieving data stored to the memory system. In some cases, each value output by a data read signal 205 may retrieve two bits (e.g., 16 bits in total may be retrieved by the data read signal 205-a and the data read signal 205-b in the scenario 301-a).

The timing diagram 300 illustrates a second scenario 301-b. In the scenario 301-b, a read command may be received at time t₁. For example, the read command may be received before a rising edge of the clock signal 230-b (e.g., before a falling edge of the clock signal 230-a). The memory system may initiate the count start signal 225-b to a first value based on the read command being received before the rising edge of the clock signal 230-b. Due to a read latency 305, the memory system may begin executing the read command according to the next falling edge of the clock signal 230-b. Based on the count start signal 225-b being initiated to the first value, the data read signal 205-b may output before the data read signal 205-a. For example, the data read signal 205-b may output a value 0 at a rising edge of the clock signal 230-b following the read latency 305 and the data read signal 205-a may output a value 0 at a falling edge of the clock signal 230-b (e.g., one unit interval of the clock signal 230-b following the output of the data read signal 205-b). The data read signals 205 may alternate outputting sequential data read values for retrieving data stored to the memory system. In some cases, each value output by a data read signal 205 may retrieve two bits (e.g., 16 bits in total may be retrieved by the data read signal 205-a and the data read signal 205-b in the scenario 301-b).

The timing diagram 300 illustrates a third scenario 301-c. In the scenario 301-c, the error control signal 235 (e.g., described with reference to FIG. 2) may be set to a value indicating one of the data read signal 205-a or the data read signal 205-b is to output an additional value for retrieving one or more error control bits (e.g., cyclic redundancy check bits). In some cases, error control bits may optionally be included as part of the read data. When included, at least one of the data read signals is to have an extra clock cycle. The data read signal 205 that outputs first may be configured to output the additional value (e.g., value 4). In the example illustrated by the scenario 301-c, the data read signal 205-a may include the additional value (e.g., similar to the scenario 301-a), such that the data read signal 205-a outputs a value 4 after the data read signal 205-b outputs a value 3. Alternatively, such techniques may be applicable to the scenario 301-b, where the data read signal 205-b may include the additional value for retrieving the error control bits.

FIG. 4 shows an example of an architecture 400 that supports techniques for read burst ordering control at a memory system in accordance with examples as disclosed herein. The architecture 400 may implement, or be implemented by, one or more aspects of the system 100, the clock circuit 200, and the timing diagram 300. For example, the architecture 400 may be included in and implemented by a memory system 110 described with reference to FIG. 1. Additionally, the architecture 400 may correspond to the first portion 201-a of the clock circuit 200 configured to output the data read signal 205-a, as described with reference to FIGS. 2 and 3. It should be noted that while the architecture 400 does not include a detailed view of the portion 201-b of the clock circuit 200, one of ordinary skill in the art will understand the techniques described with reference to the architecture 400 may be similarly applied to the portion 201-b to output the data read signal 205-b.

The architecture 400 illustrates the data read signal 205-a, the control circuit 210-a, the shift register 215-a, the multiplexer 220-a, the count start signal 225-a, the count start signal 225-b, the clock signal 230-a, and the error control signal 235 as described with reference to FIG. 2. As shown by the architecture 400, the control circuit 210-a may be an example of a latch that includes a data input, Df, a clock input, LAT, and a set input, Sf. The data input may be configured to receive the count start signal 225-b, the set input may be configured to receive the count start signal 225-a, and the clock input may be configured to receive the clock signal 230-a. In some examples, the control circuit 210-a may include a second clock input configured to receive the clock signal 230-b (e.g., LATf receiving an inversion of the clock signal 230-a). Additionally, or alternatively, the control circuit 210-a may include a reset input (e.g., Rf). The clock circuit 210-a may include an output, Q, configured to output a binary value (e.g., 0 or 1) based on the inputs to the control circuit 210-a. For example, if the count start signal 225-a is set to the first value (e.g., 0) and the count start signal 225-b is set to the second value (e.g., 1), the set input may receive the first value and force the control circuit 210-a to output a 1 (e.g., independent of the value at the data input). Alternatively, if the count start signal 225-a is set to the second value (e.g., 1) and the count start signal 225-b is set to the first value (e.g., 0), the value at the data input may transfer to the output, which may activate the shift register 215-a after a delay (e.g., allowing for the data read signal 205-b to be output first).

The shift register 215-a may include a set of latches 405 (e.g., flip-flop components). Each latch 405 may store and output a binary value (e.g., 0 or 1) according to one or more inputs at each latch 405. For example, a latch 405-a may include a data input, Df, configured to receive an output from the multiplexer 220-a, a clock input, CLK, configured to receive the clock signal 230-a, and a set input, Sf, configured to receive an output from the control circuit 210-a. For example, when both of the count start signal 225-a and the count start signal 225-b are not activated (e.g., logic 1), the control circuit 210-a may output a 0, which may force the latch 405-a to be in set state (e.g., logic 1 at the output of the latch 405-a). If the control circuit 210-a outputs a 1 (e.g., after receiving count start signal 225-a at an activated state, for example logic 0), the set input of the latch 405-a may be released from set state and may be ready to switch (e.g., to another logic value) when receiving the rising edge of the clock signal 230-a. The output of the latch 405-a may go to a subsequent latch 405 of the shift register (e.g., a latch 405-b) and to a driver 410. Additionally, other latches 405-b, 405-c, and 405-d may receive the output of the control circuit 210-a at a reset input, which may stop forcing the output of the latched 405-b, 405-c, and 405-d from a 0 and be ready to switch (e.g., to another logic value) when the output of the control circuit 210-a is a 1. Each latch 405 may output data values when receiving the rising edge of the clock signal 230-a. Thus, at each rising edge of the clock signal 230-a after receiving the output from the control circuit 210-a, a data value 1 may be sequentially shifted between the latches 405 and the driver may receive a sequence of 4 bits. As an example, the latch 405-a may correspond to a least significant bit of the sequence and the latch 405-d may correspond to a most significant bit of the sequence. Accordingly, the first output of the latches 405 after receiving the output from the control circuit 210-a may result in the driver 410 receiving 0001 corresponding to value 0, a second output of the latches 405 may result in the driver receiving 0010 corresponding to value 1, a third output of the latches 405 may result in the driver receiving 0100 corresponding to value 2, and a fourth output of the latches 405 may result in the driver receiving 1000 corresponding to value 3. The driver may output the value corresponding to the bit sequence received, which may correspond to the data read signal 205-a.

The shift register 215-a may include an additional latch 405-e, which may be an additional value of the data read signal 205-a for retrieving error control bits (e.g., cyclic redundancy check bits). The error control signal 235 (or, in some examples, an inversion of the error control signal 235) and the output of the control circuit 210-a may be input to logic 420, which may be received at a reset input of the latch 405-e. When the control circuit 210-a triggers the set/reset of the other latches 405, the latch 405-e may be selectively reset according to the logic 420. For example, if the error control signal 235 indicates to retrieve error control bits, the latch 405-e may receive the reset signal and output a 0.

Additionally, whether the latch 405-e contributes a bit to the data read signal 205-a may be based on the output of the multiplexer 220-a, which may be based on the error control signal 235 and the count start signal 225-a. For example, the error control signal 235 and the count start signal 225-a may be input to logic 415 (e.g., a NAND gate), which may perform a logical operation using the error control signal 235 and the count start signal 225-a. The output of the logic 415 may be input to the multiplexer 220-a and may serve as a selection bit for determining the output of the multiplexer 220-a. For example, the output of the latch 405-d and the output of the latch 405-e may each be inputs to the multiplexer 220-a, where one of the two inputs may be output by the multiplexer 220-a according to the selection bit. As an example, if the logic 415 outputs a first value (e.g., logic 0 or 1, based on an implementation of the multiplexer 220-a) as the selection bit, the multiplexer 220-a may output the value received from the latch 405-d, and if the logic 415 outputs a second value (e.g., the other of logic 0 or 1) as the selection bit, the multiplexer 220-a may output the value received from the latch 405-e. The output of the multiplexer 220-a may be input to the data input of the latch 405-a. Thus, the multiplexer 220-a may provide a selection of whether the value of latch 405-e is shifted and included in the data read signal 205-a when operating the shift register 215-a.

In some cases, the logic 415 may prevent both data read signals 205 from including the additional value when the error control signal 235 is set to a value indicating the read data burst includes error control bits. For example, the portion 201-b of the clock circuit 200 may include similar logic 415 configured to receive the count start signal 225-b and the error control signal 235 and output to the multiplexer 220-b (e.g., described with reference to FIG. 2). When the error control signal 235 is set (e.g., indicating to retrieve error control bits via one of the data read signals 205) and the count start signal 225-a is initiated to the first value (e.g., indicating the data read signal 205-a should output before the data read signal 205-b), the logic 415 may output a selection bit selecting for the latch 405-e to output to the latch 405-a, thereby including the additional value in the data read signal 205-a. In this example, the count start signal 225-b may be maintained at the second value, and may be input to the logic 415 with the error control signal 235. Due to the count start signal 225-b being maintained at the second value, the multiplexer 220-b may receive a selection bit selecting for a latch 405-d of the shift register 215-b to output to a latch 405-a of the shift register 215-b, thereby preventing the data read signal 205-b from including the additional value.

FIG. 5 shows an example of a timing diagram 500 that supports techniques for read burst ordering control at a memory system in accordance with examples as disclosed herein. The timing diagram 500 may implement, or be implemented by, one or more aspects of the system 100, the clock circuit 200, the timing diagram 300, and the architecture 400. For example, the timing diagram 500 may be implemented at a memory system 110 and illustrates waveforms associated with the count start signal 225-a, the clock signal 230-a, the data read signal 205-a, the count start signal 225-b, the clock signal 230-b, and the data read signal 205-b, as described herein.

At time t₁, the memory system may initiate the count start signal 225-a to a first value (e.g., drive low). In some cases, the memory system may initiate the count start signal 225-a in response to receiving a command to read data stored to the memory system. The memory system may initiate the count start signal 225-a based on the command being received before a rising edge of the clock signal 230-b. For example, due to read latency, the memory system may begin executing the command one unit interval after the rising edge of the clock signal 230-b (e.g., a rising edge of the clock signal 230-a). In some cases, the memory system may maintain the count start signal 225-b at a second value (e.g., maintain high). Executing the command may include outputting the data read signal 205-a and the data read signal 205-b in an alternating pattern, where the values of the count start signal 225-a and the count start signal 225-b may determine which data read signal is output first.

For example, the memory system may output a data read signal 205-a-1, which may correspond to a first value of the data read signal 205-a (e.g., value 0) for retrieving a first set of bits of data. After a delay from outputting the data read signal 205-a-1, the memory system may output a data read signal 205-b-1, which may correspond to a second value of the data read signal 205-b (e.g., value 0) for retrieving a second set of bits of the data. The memory system may continue outputting the values of the data read signals 205 in the alternating pattern, for example (at time t₂) outputting a data read signal 205-a-2 (e.g., value 1), followed by (at time t₃) a data read signal 205-b-2 (e.g., value 1), followed by a data read signal 205-a-3 (e.g., value 2), followed by a data read signal 205-b-3 (e.g., value 2), followed by a data read signal 205-a-4 (e.g., value 3), followed by a data read signal 205-b-4 (e.g., value 3). In some examples, if the error control signal 235 is set, the data read signal 205-a may output an additional value for retrieving error control bits (e.g., data read signal 205-a-5 (not shown)) after the data read signal 205-b-4.

At time t₄, the memory system may initiate the count start signal 225-b to the first value based on receiving a second read command. In some cases, the memory system may initiate the count start signal 225-b to the first value and may maintain the count start signal 225-a at the second value based on the command being received before a rising edge of the clock signal 230-a. For example, due to read latency, the memory system may begin executing the command one unit interval after the rising edge of the clock signal 230-a (e.g., a rising edge of the clock signal 230-b), which may result in the read signal 205-b being output before the read signal 205-a. Executing the second read command may include the memory system outputting the data read signal 205-b-1, followed by the data read signal 205-a-1, followed by the data read signal 205-b-2, followed by the data read signal 205-a-2, followed by the data read signal 205-b-3, followed by the data read signal 205-a-3, followed by the data read signal 205-b-4, followed by the data read signal 205-a-4. In some cases, if the error control signal 235 is set, the data read signal 205-b may output an additional value for retrieving error control bits (e.g., data read signal 205-b-5 (not shown)) after the data read signal 205-a-4.

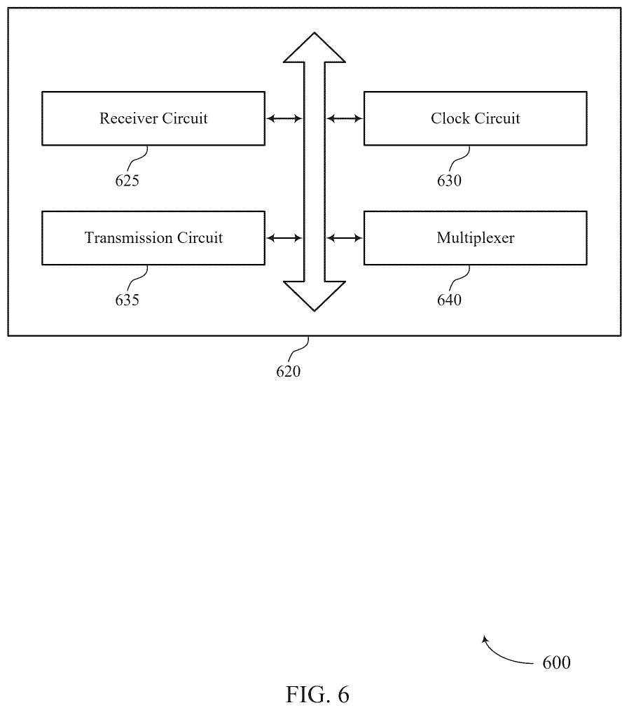

FIG. 6 shows a block diagram 600 of a memory system 620 that supports techniques for read burst ordering control at a memory system in accordance with examples as disclosed herein. The memory system 620 may be an example of aspects of a memory system as described with reference to FIGS. 1 through 5. The memory system 620, or various components thereof, may be an example of means for performing various aspects of techniques for read burst ordering control at a memory system as described herein. For example, the memory system 620 may include a receiver circuit 625, a clock circuit 630, a transmission circuit 635, a multiplexer 640, or any combination thereof. Each of these components, or components of subcomponents thereof (e.g., one or more processors, one or more memories), may communicate, directly or indirectly, with one another (e.g., via one or more buses).

The receiver circuit 625 may be configured as or otherwise support a means for receiving, by a receiver circuit, a read command to retrieve data. In some examples, the receiver circuit 625 may be configured as or otherwise support a means for identifying, by the receiver circuit, whether the read command is received before one of a rising or falling edge of a first clock signal of a divided clock or before one of a rising or falling edge of a second clock signal of the divided clock. In some examples, the receiver circuit 625 may be configured as or otherwise support a means for initiating, by the receiver circuit, a signal based at least in part on the read command being received before the rising or falling edge of the first clock signal or the rising or falling edge of the second clock signal. The clock circuit 630 may be configured as or otherwise support a means for generating, by a clock circuit, two data read signals to control burst ordering for transmitting the data based at least in part on the signal, the clock circuit including a first shift register to generate a first data read signal and a second shift register to generate a second data read signal, where the output of the first shift register or the second shift register is configured to be delayed relative to the other shift register based at least in part on whether the read command is received before the rising or falling edge of the first clock signal or the rising or falling edge of the second clock signal.

In some examples, the clock circuit 630 may include a first control circuit coupled with the first shift register and a second control circuit coupled with the second shift register, where the signal includes a first count start signal or a second count start signal based at least in part on whether the read command is received before the rising or falling edge of the first clock signal or the rising or falling edge of the second clock signal, where each of the first control circuit and the second control circuit is configured to receive the first count start signal and the second count start signal.

In some examples, the clock circuit 630 may be configured as or otherwise support a means for initiating the first count start signal to a first value and maintaining the second count start signal at a second value based at least in part on the read command being received before the rising or falling edge of the first clock signal. In some examples, the clock circuit 630 may be configured as or otherwise support a means for maintaining the first count start signal at the second value and initiating the second count start signal to the first value based at least in part on the read command being received before the rising or falling edge of the second clock signal.

In some examples, the clock circuit 630 may be configured as or otherwise support a means for delaying, by the clock circuit, the output of the second shift register relative to the output of the first shift register based at least in part on the first count start signal having the first value and the second count start signal having the second value. In some examples, the clock circuit 630 may be configured as or otherwise support a means for delaying, by the clock circuit, the output of the first shift register relative to the output of the second shift register based at least in part on the first count start signal having the second value and the second count start signal having the first value.

In some examples, the first control circuit includes a first latch with a first clock input coupled with the first clock signal, a data input, a set/reset input, and an output configured to activate the first shift register, the data input coupled with the second count start signal and the set/reset input coupled with the first count start signal, where, in response to the read command being received before the rising or falling edge of the first clock signal, the set/reset input of the first latch changes value and forces the output of the first latch to a value that initiates the first shift register; and the second control circuit includes a second latch with a first clock input coupled with the second clock signal, a data input, a set/reset input, and an output configured to activate the second shift register, the data input coupled with the first count start signal and the set/reset input coupled with the second count start signal, where the data input of the second latch changes value in response to the read command being received before the rising or falling edge of the first clock signal, where the output of the second latch changes value and initiates the second shift register in response to data input changing value and the second clock input satisfying a criterion, and where the second shift register is initiated after the first shift register is initiated based at least in part on the criterion being satisfied.

In some examples, the clock circuit 630 may be configured as or otherwise support a means for receiving, by the clock circuit, a second signal indicating whether the data includes one or more error control bits.

In some examples, the clock circuit 630 may be configured as or otherwise support a means for activating, by the clock circuit, an additional component of the first shift register based at least in part on receiving the second signal.

In some examples, the multiplexer 640 may be configured as or otherwise support a means for receiving, by a multiplexer of the clock circuit, a first input from the additional component of the first shift register, a second input from a second component of the first shift register, and the second signal as a control input. In some examples, the multiplexer 640 may be configured as or otherwise support a means for outputting, by the multiplexer, one of the first input or the second input based at least in part on the value of the second signal.

In some examples, the transmission circuit 635 may be configured as or otherwise support a means for transmitting, by a transmitter circuit, the data using the two data read signals output by the clock circuit.

In some examples, the described functionality of the memory system 620, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 620, or various components thereof, may be implemented at least in part by instructions (e.g., stored in memory, non-transitory computer-readable medium) executable by such at least one processor.

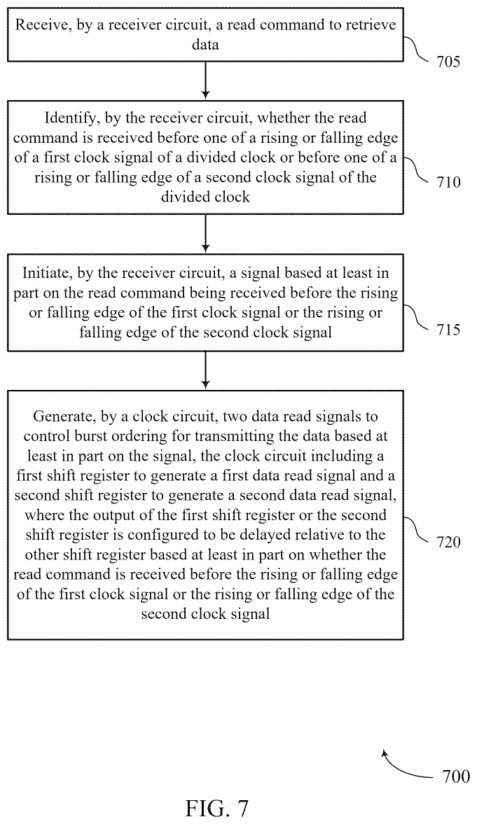

FIG. 7 shows a flowchart illustrating a method 700 that supports techniques for read burst ordering control at a memory system in accordance with examples as disclosed herein. The operations of method 700 may be implemented by a memory system or its components as described herein. For example, the operations of method 700 may be performed by a memory system as described with reference to FIGS. 1 through 6. In some examples, a memory system may execute a set of instructions to control the functional elements of the device to perform the described functions. Additionally, or alternatively, the memory system may perform aspects of the described functions using special-purpose hardware.

At 705, the method may include receiving, by a receiver circuit, a read command to retrieve data. In some examples, aspects of the operations of 705 may be performed by a receiver circuit 625 as described with reference to FIG. 6.

At 710, the method may include identifying, by the receiver circuit, whether the read command is received before one of a rising or falling edge of a first clock signal of a divided clock or before one of a rising or falling edge of a second clock signal of the divided clock. In some examples, aspects of the operations of 710 may be performed by a receiver circuit 625 as described with reference to FIG. 6.

At 715, the method may include initiating, by the receiver circuit, a signal based at least in part on the read command being received before the rising or falling edge of the first clock signal or the rising or falling edge of the second clock signal. In some examples, aspects of the operations of 715 may be performed by a receiver circuit 625 as described with reference to FIG. 6.

At 720, the method may include generating, by a clock circuit, two data read signals to control burst ordering for transmitting the data based at least in part on the signal, the clock circuit including a first shift register to generate a first data read signal and a second shift register to generate a second data read signal, where the output of the first shift register or the second shift register is configured to be delayed relative to the other shift register based at least in part on whether the read command is received before the rising or falling edge of the first clock signal or the rising or falling edge of the second clock signal. In some examples, aspects of the operations of 720 may be performed by a clock circuit 630 as described with reference to FIG. 6.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for receiving, by a receiver circuit, a read command to retrieve data; identifying, by the receiver circuit, whether the read command is received before one of a rising or falling edge of a first clock signal of a divided clock or before one of a rising or falling edge of a second clock signal of the divided clock; initiating, by the receiver circuit, a signal based at least in part on the read command being received before the rising or falling edge of the first clock signal or the rising or falling edge of the second clock signal; and generating, by a clock circuit, two data read signals to control burst ordering for transmitting the data based at least in part on the signal, the clock circuit including a first shift register to generate a first data read signal and a second shift register to generate a second data read signal, where the output of the first shift register or the second shift register is configured to be delayed relative to the other shift register based at least in part on whether the read command is received before the rising or falling edge of the first clock signal or the rising or falling edge of the second clock signal.
Aspect 2: The method, apparatus, or non-transitory computer-readable medium of aspect 1, where the clock circuit includes a first control circuit coupled with the first shift register and a second control circuit coupled with the second shift register, where the signal includes a first count start signal or a second count start signal based at least in part on whether the read command is received before the rising or falling edge of the first clock signal or the rising or falling edge of the second clock signal, where each of the first control circuit and the second control circuit is configured to receive the first count start signal and the second count start signal.
Aspect 3: The method, apparatus, or non-transitory computer-readable medium of aspect 2, further including operations, features, circuitry, logic, means, or instructions, or any combination thereof for initiating the first count start signal to a first value and maintaining the second count start signal at a second value based at least in part on the read command being received before the rising or falling edge of the first clock signal and maintaining the first count start signal at the second value and initiating the second count start signal to the first value based at least in part on the read command being received before the rising or falling edge of the second clock signal.
Aspect 4: The method, apparatus, or non-transitory computer-readable medium of aspect 3, further including operations, features, circuitry, logic, means, or instructions, or any combination thereof for delaying, by the clock circuit, the output of the second shift register relative to the output of the first shift register based at least in part on the first count start signal having the first value and the second count start signal having the second value and delaying, by the clock circuit, the output of the first shift register relative to the output of the second shift register based at least in part on the first count start signal having the second value and the second count start signal having the first value.
Aspect 5: The method, apparatus, or non-transitory computer-readable medium of any of aspects 2 through 4, where the first control circuit includes a first latch with a first clock input coupled with the first clock signal, a data input, a set/reset input, and an output configured to activate the first shift register, the data input coupled with the second count start signal and the set/reset input coupled with the first count start signal, where, in response to the read command being received before the rising or falling edge of the first clock signal, the set/reset input of the first latch changes value and forces the output of the first latch to a value that initiates the first shift register; and the second control circuit includes a second latch with a first clock input coupled with the second clock signal, a data input, a set/reset input, and an output configured to activate the second shift register, the data input coupled with the first count start signal and the set/reset input coupled with the second count start signal, where the data input of the second latch changes value in response to the read command being received before the rising or falling edge of the first clock signal, where the output of the second latch changes value and initiates the second shift register in response to data input changing value and the second clock input satisfying a criterion, and where the second shift register is initiated after the first shift register is initiated based at least in part on the criterion being satisfied.
Aspect 6: The method, apparatus, or non-transitory computer-readable medium of any of aspects 1 through 5, further including operations, features, circuitry, logic, means, or instructions, or any combination thereof for receiving, by the clock circuit, a second signal indicating whether the data includes one or more error control bits.
Aspect 7: The method, apparatus, or non-transitory computer-readable medium of aspect 6, further including operations, features, circuitry, logic, means, or instructions, or any combination thereof for activating, by the clock circuit, an additional component of the first shift register based at least in part on receiving the second signal.
Aspect 8: The method, apparatus, or non-transitory computer-readable medium of aspect 7, further including operations, features, circuitry, logic, means, or instructions, or any combination thereof for receiving, by a multiplexer of the clock circuit, a first input from the additional component of the first shift register, a second input from a second component of the first shift register, and the second signal as a control input and outputting, by the multiplexer, one of the first input or the second input based at least in part on the value of the second signal.
Aspect 9: The method, apparatus, or non-transitory computer-readable medium of any of aspects 1 through 8, further including operations, features, circuitry, logic, means, or instructions, or any combination thereof for transmitting, by a transmitter circuit, the data using the two data read signals output by the clock circuit.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 10: A memory system, including: a memory device; a receiver circuit configured to: receive a read command to retrieve data; identify whether the read command is received before one of a rising or falling edge of a first clock signal of a divided clock or before one of a rising or falling edge of a second clock signal of the divided clock; and initiate a signal based at least in part on the read command being received before the rising or falling edge of the first clock signal or the rising or falling edge of the second clock signal; and a clock circuit configured to generate two data read signals to control burst ordering for transmitting the data based at least in part on the signal, the clock circuit including a first shift register to generate a first data read signal and a second shift register to generate a second data read signal, where the output of the first shift register or the second shift register is configured to be delayed relative to the other shift register based at least in part on whether the read command is received before the rising or falling edge of the first clock signal or the rising or falling edge of the second clock signal.
Aspect 11: The memory system of aspect 10, where the clock circuit further includes: a first control circuit coupled with the first shift register and a second control circuit coupled with the second shift register, where the signal includes a first count start signal or a second count start signal based at least in part on whether the read command is received before the rising or falling edge of the first clock signal or the rising or falling edge of the second clock signal, where each of the first control circuit and the second control circuit is configured to receive the first count start signal and the second count start signal.
Aspect 12: The memory system of aspect 11, where: the first count start signal is initiated to a first value and the second count start signal remains at a second value based at least in part on the read command being received before the rising or falling edge of the first clock signal; and the first count start signal remains at the second value and the second count start signal is initiated to the first value based at least in part on when the read command being received before the rising or falling edge of the second clock signal.
Aspect 13: The memory system of aspect 12, where the clock circuit is further configured to: delay the output of the second shift register relative to the output of the first shift register based at least in part on the first count start signal having the first value and the second count start signal having the second value; and delay the output of the first shift register relative to the output of the second shift register based at least in part on the first count start signal having the second value and the second count start signal having the first value.
Aspect 14: The memory system of any of aspects 11 through 13, where: the first control circuit includes a first latch with a first clock input coupled with the first clock signal, a data input, a set/reset input, and an output configured to activate the first shift register, the data input coupled with the second count start signal and the set/reset input coupled with the first count start signal, where, in response to the read command being received before the rising or falling edge of the first clock signal, the set/reset input of the first latch changes value and forces the output of the first latch to a value that initiates the first shift register; and the second control circuit includes a second latch with a first clock input coupled with the second clock signal, a data input, a set/reset input, and an output configured to activate the second shift register, the data input coupled with the first count start signal and the set/reset input coupled with the second count start signal, where the data input of the second latch changes value in response to the read command being received before the rising or falling edge of the first clock signal, where the output of the second latch changes value and initiates the second shift register in response to data input changing value and the second clock input satisfying a criterion, and where the second shift register is initiated after the first shift register is initiated based at least in part on the criterion being satisfied.
Aspect 15: The memory system of any of aspects 10 through 14, where the clock circuit is configured to: receive a second signal indicating whether the data includes one or more error control bits.
Aspect 16: The memory system of aspect 15, where the clock circuit is configured to: activate an additional component of the first shift register based at least in part on receiving the second signal.
Aspect 17: The memory system of aspect 16, where the clock circuit further includes: a multiplexer configured to receive a first input from the additional component of the first shift register, a second input from a second component of the first shift register, and the second signal as a control input, the multiplexer configured to output one of the first input or the second input based at least in part on the value of the second signal.
Aspect 18: The memory system of any of aspects 15 through 17, where the one or more error control bits in the data include one or more cyclic redundancy check bits.
Aspect 19: The memory system of any of aspects 10 through 18, where: the first shift register includes a first plurality of flip-flops configured to sequentially shift data to control burst ordering for transmitting the data; and the second shift register includes a second plurality of flip-flops configured to sequentially shift data to control burst ordering for transmitting the data.
Aspect 20: The memory system of any of aspects 10 through 19, where: a transmitter circuit configured to transmit the data using the two data read signals output by the clock circuit.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
a memory device;
a receiver circuit configured to:
receive a read command to retrieve data;
identify whether the read command is received before one of a rising or falling edge of a first clock signal of a divided clock or before one of a rising or falling edge of a second clock signal of the divided clock; and
initiate a signal based at least in part on the read command being received before the rising or falling edge of the first clock signal or the rising or falling edge of the second clock signal; and
a clock circuit configured to generate two data read signals to control burst ordering for transmitting the data based at least in part on the signal, the clock circuit comprising a first shift register to generate a first data read signal and a second shift register to generate a second data read signal, wherein the output of the first shift register or the second shift register is configured to be delayed relative to the other shift register based at least in part on whether the read command is received before the rising or falling edge of the first clock signal or the rising or falling edge of the second clock signal.

2. The memory system of claim 1, wherein the clock circuit further comprises:
a first control circuit coupled with the first shift register and a second control circuit coupled with the second shift register, wherein the signal comprises a first count start signal or a second count start signal based at least in part on whether the read command is received before the rising or falling edge of the first clock signal or the rising or falling edge of the second clock signal, wherein each of the first control circuit and the second control circuit is configured to receive the first count start signal and the second count start signal.

3. The memory system of claim 2, wherein:
the first count start signal is initiated to a first value and the second count start signal remains at a second value based at least in part on the read command being received before the rising or falling edge of the first clock signal; and
the first count start signal remains at the second value and the second count start signal is initiated to the first value based at least in part on when the read command being received before the rising or falling edge of the second clock signal.

4. The memory system of claim 3, wherein the clock circuit is further configured to:
delay the output of the second shift register relative to the output of the first shift register based at least in part on the first count start signal having the first value and the second count start signal having the second value; and
delay the output of the first shift register relative to the output of the second shift register based at least in part on the first count start signal having the second value and the second count start signal having the first value.

5. The memory system of claim 2, wherein:
the first control circuit comprises a first latch with a first clock input coupled with the first clock signal, a data input, a set/reset input, and an output configured to activate the first shift register, the data input coupled with the second count start signal and the set/reset input coupled with the first count start signal, wherein, in response to the read command being received before the rising or falling edge of the first clock signal, the set/reset input of the first latch changes value and forces the output of the first latch to a value that initiates the first shift register; and
the second control circuit comprises a second latch with a first clock input coupled with the second clock signal, a data input, a set/reset input, and an output configured to activate the second shift register, the data input coupled with the first count start signal and the set/reset input coupled with the second count start signal, wherein the data input of the second latch changes value in response to the read command being received before the rising or falling edge of the first clock signal, wherein the output of the second latch changes value and initiates the second shift register in response to data input changing value and the second clock input satisfying a criterion, and wherein the second shift register is initiated after the first shift register is initiated based at least in part on the criterion being satisfied.

6. The memory system of claim 1, wherein the clock circuit is configured to:
receive a second signal indicating whether the data comprises one or more error control bits.

7. The memory system of claim 6, wherein the clock circuit is configured to:
activate an additional component of the first shift register based at least in part on receiving the second signal.

8. The memory system of claim 7, wherein the clock circuit further comprises:
a multiplexer configured to receive a first input from the additional component of the first shift register, a second input from a second component of the first shift register, and the second signal as a control input, the multiplexer configured to output one of the first input or the second input based at least in part on the value of the second signal.

9. The memory system of claim 6, wherein the one or more error control bits in the data comprise one or more cyclic redundancy check bits.

10. The memory system of claim 1, wherein:
the first shift register comprises a first plurality of flip-flops configured to sequentially shift data to control burst ordering for transmitting the data; and
the second shift register comprises a second plurality of flip-flops configured to sequentially shift data to control burst ordering for transmitting the data.

11. The memory system of claim 1, wherein:
a transmitter circuit configured to transmit the data using the two data read signals output by the clock circuit.

12. A method by a memory system, comprising:
receiving, by a receiver circuit, a read command to retrieve data;
identifying, by the receiver circuit, whether the read command is received before one of a rising or falling edge of a first clock signal of a divided clock or before one of a rising or falling edge of a second clock signal of the divided clock;
initiating, by the receiver circuit, a signal based at least in part on the read command being received before the rising or falling edge of the first clock signal or the rising or falling edge of the second clock signal; and
generating, by a clock circuit, two data read signals to control burst ordering for transmitting the data based at least in part on the signal, the clock circuit comprising a first shift register to generate a first data read signal and a second shift register to generate a second data read signal, wherein the output of the first shift register or the second shift register is configured to be delayed relative to the other shift register based at least in part on whether the read command is received before the rising or falling edge of the first clock signal or the rising or falling edge of the second clock signal.

13. The method of claim 12, wherein the clock circuit further comprises a first control circuit coupled with the first shift register and a second control circuit coupled with the second shift register, wherein the signal comprises a first count start signal or a second count start signal based at least in part on whether the read command is received before the rising or falling edge of the first clock signal or the rising or falling edge of the second clock signal, wherein each of the first control circuit and the second control circuit is configured to receive the first count start signal and the second count start signal.

14. The method of claim 13, further comprising:
initiating the first count start signal to a first value and maintaining the second count start signal at a second value based at least in part on the read command being received before the rising or falling edge of the first clock signal; and
maintaining the first count start signal at the second value and initiating the second count start signal to the first value based at least in part on the read command being received before the rising or falling edge of the second clock signal.

15. The method of claim 14, further comprising:
delaying, by the clock circuit, the output of the second shift register relative to the output of the first shift register based at least in part on the first count start signal having the first value and the second count start signal having the second value; and
delaying, by the clock circuit, the output of the first shift register relative to the output of the second shift register based at least in part on the first count start signal having the second value and the second count start signal having the first value.

16. The method of claim 13, wherein the first control circuit comprises a first latch with a first clock input coupled with the first clock signal, a data input, a set/reset input, and an output configured to activate the first shift register, the data input coupled with the second count start signal and the set/reset input coupled with the first count start signal, wherein, in response to the read command being received before the rising or falling edge of the first clock signal, the set/reset input of the first latch changes value and forces the output of the first latch to a value that initiates the first shift register; and the second control circuit comprises a second latch with a first clock input coupled with the second clock signal, a data input, a set/reset input, and an output configured to activate the second shift register, the data input coupled with the first count start signal and the set/reset input coupled with the second count start signal, wherein the data input of the second latch changes value in response to the read command being received before the rising or falling edge of the first clock signal, wherein the output of the second latch changes value and initiates the second shift register in response to data input changing value and the second clock input satisfying a criterion, and wherein the second shift register is initiated after the first shift register is initiated based at least in part on the criterion being satisfied.

17. The method of claim 12, further comprising:
receiving, by the clock circuit, a second signal indicating whether the data comprises one or more error control bits.

18. The method of claim 17, further comprising:
activating, by the clock circuit, an additional component of the first shift register based at least in part on receiving the second signal.

19. The method of claim 18, further comprising:
receiving, by a multiplexer of the clock circuit, a first input from the additional component of the first shift register, a second input from a second component of the first shift register, and the second signal as a control input; and
outputting, by the multiplexer, one of the first input or the second input based at least in part on the value of the second signal.

20. A memory system, comprising:
a memory device; and
processing circuitry coupled with the memory device and configured to cause the memory system to:
receive a read command to retrieve data;
identify whether the read command is received before one of a rising or falling edge of a first clock signal of a divided clock or before one of a rising or falling edge of a second clock signal of the divided clock;
initiate a signal based at least in part on the read command being received before the rising or falling edge of the first clock signal or the rising or falling edge of the second clock signal; and
generate two data read signals to control burst ordering for transmitting the data based at least in part on the signal, the memory system comprising a first shift register to generate a first data read signal and a second shift register to generate a second data read signal, wherein the output of the first shift register or the second shift register is configured to be delayed relative to the other shift register based at least in part on whether the read command is received before the rising or falling edge of the first clock signal or the rising or falling edge of the second clock signal.
